(19) United States
(12) Patent Application Publication
(10) Pub. No.: US 2026/0173708 A1
(43) Pub. Date: Jun. 18, 2026

(54) DISPLAY DEVICE AND ELECTRONIC DEVICE INCLUDING THE SAME

(71) Applicant: Samsung Display Co., Ltd., Yongin-si (KR)

(72) Inventors: HEECHUL JEON, Yongin-si (KR); KYUNGMIN KIM, Yongin-si (KR); EUNKYUNG YANG, Yongin-si (KR); HYEONKYUN OH, Yongin-si (KR); SANG YOUN HAN, Yongin-si (KR); SEOYOUNG HWANG, Yongin-si (KR)

(21) Appl. No.: 19/319,543

(22) Filed: Sep. 4, 2025

(30) Foreign Application Priority Data
Dec. 12, 2024 (KR) 10-2024-0184583

(51) Int. Cl. H10K 59/40; H10K 59/131; H10K 59/38; H10K 59/80; H10K 102/00

(52) U.S. Cl. CPC H10K 59/40; H10K 59/131; H10K 59/38; H10K 59/8792; H10K 2102/341

(57) ABSTRACT

A display device includes a substrate with a display area and a pad area. A transistor is in the display area, and multiple pads are in the pad area, each pad with four sequentially stacked pad electrodes. An insulating layer covers an edge of a third pad electrode. A touch layer, on the transistor, extends from the display area to the pad area and includes: a first touch insulating layer contacting the third pad electrode and an upper surface of the insulating layer; a first touch electrode on the first touch insulating layer; a second touch insulating layer covering the first touch electrode and extending to the pad area; a third touch insulating layer with an organic insulating material; and a second touch electrode on the third touch insulating layer, connected to the first touch electrode. An anti-etching layer is in the pad area on the first touch insulating layer.

### CROSS-REFERENCE TO RELATED APPLICATION

The present application claims priority to and the benefit of Korean Patent Application No. 10-2024-0184583, filed on Dec. 12, 2024, in the Korean Intellectual Property Office, the entire disclosure of which is incorporated herein by reference.

### BACKGROUND

### 1. Field

One or more embodiments of the present disclosure relate to a display device and an electronic device including the same. For example, one or more embodiments of the present disclosure relate to a display device that provides visual information and an electronic device including the same.

### 2. Description of the Related Art

As information technology progresses, the importance of display devices, which are a connection medium between users and information, is emerging. Accordingly, the use of display devices, such as liquid crystal display devices, organic light emitting display devices, and/or plasma display devices, is increasing.

### SUMMARY

One or more aspects of embodiments of the present disclosure are directed toward a display device with improved reliability.

One or more aspects of embodiments of the present disclosure are directed toward an electronic device including the display device.

Additional aspects will be set forth in part in the description which follows and, in part, will be apparent from the description, or may be learned by practice of the presented embodiments.

According to one or more embodiments of the present disclosure, a display device includes: a substrate including a display area and a pad area located on a (e.g., one) side of the display area; a transistor located in the display area on the substrate; a plurality of pads located in the pad area, each of the pads including stacked first, second, third, and fourth pad electrodes along a thickness direction; an insulating layer covering an edge of the third pad electrode; a touch layer including a first touch insulating layer located on the transistor, extending from the display area to the pad area, and contacting the third pad electrode and an upper surface of the insulating layer, a first touch electrode located on the first touch insulating layer, a second touch insulating layer located on the first touch insulating layer, covering the first touch electrode, extending from the display area to the pad area, and covering an end of the first touch insulating layer in the pad area, a third touch insulating layer located on the second touch insulating layer and including an organic insulating material, and a second touch electrode located on the third touch insulating layer and connected to the first touch electrode; and an anti-etching layer located in the pad area on the first touch insulating layer.

In one or more embodiments, the anti-etching layer may include a same material as the first touch electrode.

In one or more embodiments, the anti-etching layer may be located between the first touch insulating layer and the second touch insulating layer.

In one or more embodiments, the anti-etching layer may directly contact an upper surface of the first touch insulating layer and a lower surface of the second touch insulating layer.

In one or more embodiments, an edge of the anti-etching layer may at least partially overlap an edge of the fourth pad electrode in a plan view.

In one or more embodiments, a lower surface of the second touch insulating layer may contact the third pad electrode, the first touch insulating layer, and the anti-etching layer.

In one or more embodiments, the anti-etching layer may include a same material as the third touch insulating layer.

In one or more embodiments, an end of the fourth pad electrode may contact an upper surface of the anti-etching layer.

In one or more embodiments, a lower surface of the fourth pad electrode may contact the third pad electrode, the second touch insulating layer, and the anti-etching layer.

In one or more embodiments, the anti-etching layer may be located between the second touch insulating layer and an end of the fourth pad electrode in the pad area.

In one or more embodiments, an opening exposing the third pad electrode may be defined in the anti-etching layer. The fourth pad electrode may be located in the opening.

In one or more embodiments, the first touch insulating layer may be spaced and/or apart (e.g., spaced apart or separated) from the fourth pad electrode in the pad area.

In one or more embodiments, the transistor may include an active pattern, a first gate electrode located on the active pattern, and a source electrode and a drain electrode each connected to the active pattern. The display device may further include a second gate electrode located in the display area on the first gate electrode. The first pad electrode may include a same material as the first gate electrode or the second gate electrode. The second pad electrode may include a same material as the source electrode and the drain electrode.

In one or more embodiments, the display device may further include a connection electrode located in the display area on the source electrode and/or the drain electrode, and connected to the transistor. The third pad electrode may include a same material as the connection electrode.

In one or more embodiments, the fourth pad electrode may include a same material as the second touch electrode.

In one or more embodiments, the display device may further include an anti-reflection layer including a black matrix located in the display area on the second touch electrode, a color filter located on the black matrix, and an overcoat layer covering the color filter.

According to one or more embodiments of the present disclosure, an electronic device includes a display device including: a substrate including a display area and a pad area located on a (e.g., one) side of the display area; a transistor located in the display area on the substrate; a plurality of pads located in the pad area, each of the pads including stacked first, second, third, and fourth pad electrodes along a thickness direction; an insulating layer covering an edge of the third pad electrode; a touch layer located on the transistor; and an anti-etching layer located in the pad area on a first touch insulating layer, and a processor that controls the display device. The touch layer may include the first touch insulating layer extending from the display area to the pad area and contacting the third pad electrode and an upper surface of the insulating layer, a first touch electrode located on the first touch insulating layer, a second touch insulating layer located on the first touch insulating layer, covering the first touch electrode, extending from the display area to the pad area, and covering an end of the first touch insulating layer in the pad area, a third touch insulating layer located on the second touch insulating layer and including an organic insulating material, and a second touch electrode located on the third touch insulating layer and connected to the first touch electrode.

In one or more embodiments, the anti-etching layer may include a same material as the first touch electrode. The anti-etching layer may be located between the first touch insulating layer and the second touch insulating layer. An edge of the anti-etching layer may at least partially overlap an edge of the fourth pad electrode in a plan view.

In one or more embodiments, the anti-etching layer may directly contact an upper surface of the first touch insulating layer and a lower surface of the second touch insulating layer. The lower surface of the second touch insulating layer may contact the third pad electrode, the first touch insulating layer, and the anti-etching layer.

In one or more embodiments, the anti-etching layer may include a same material as the third touch insulating layer. The anti-etching layer may be located between the second touch insulating and the fourth pad electrode. A lower surface of the fourth pad electrode may contact the third pad electrode, the second touch insulating layer, and the anti-etching layer.

The display device according to one or more embodiments of the present disclosure may include the second touch insulating layer in the pad area, and the second touch insulating layer, together with the fist touch insulating layer, may form an inorganic layer of sufficient thickness to resist external pressure. Accordingly, during the compression process to attach a driving integrated circuit and a circuit board onto the substrate, cracks may be prevented or reduced from occurring in the first touch insulating layer, and corrosion of the pads due to moisture permeation into the insulating layer through the cracks is suppressed or reduced, thereby preventing or reducing defects in the display device.

Additionally, the display device may include the anti-etching layer. The anti-etching layer may prevent or reduce the fist touch insulating layer from being removed when the fourth pad electrode is etched. Accordingly, during the compression process to attach the driving integrated circuit and the circuit board onto the substrate, cracks may be prevented or reduced from occurring in the first touch insulating layer, and corrosion of the pads due to moisture permeation into the insulating layer through the cracks is suppressed or reduced, thereby preventing or reducing defects in the display device.

Consequently, the reliability of the display device may be improved.

### BRIEF DESCRIPTION OF THE DRAWINGS

Illustrative, non-limiting embodiments will be more clearly understood from the following detailed description in conjunction with the accompanying drawings; however, they may be embodied in different forms and should not be construed as limited to example embodiments set forth herein. Rather, these embodiments are provided so that this disclosure will be thorough and complete, and will fully convey the scope of the example embodiments to those skilled in the art. The above and other aspects, features, and advantages of certain embodiments of the present disclosure will be more apparent from the following description taken in conjunction with the accompanying drawings.

FIG. 1 is a plan view illustrating a display device according to one or more embodiments of the present disclosure.

FIG. 2 is a cross-sectional view taken along the line I-I′ of FIG. 1 according to one or more embodiments of the present disclosure.

FIG. 3 is an enlarged plan view illustrating an area A of FIG. 1 according to one or more embodiments of the present disclosure.

FIG. 4 is a cross-sectional view taken along the line II-II′ of FIG. 1 according to one or more embodiments of the present disclosure.

FIG. 5 is a cross-sectional view taken along the line III-III′ of FIG. 3 according to one or more embodiments of the present disclosure.

FIGS. 6, 7, 8, 9, 10, 11, 12, 13, 14, 15, and 16 are cross-sectional views illustrating an example of a method of manufacturing the display device of FIGS. 4 and 5 according to one or more embodiments of the present disclosure.

FIG. 17 is a cross-sectional view taken along the line III-III′ of FIG. 3 according to one or more embodiments of the present disclosure.

FIG. 18 is a cross-sectional view taken along the line III-III′ of FIG. 3 according to one or more embodiments of the present disclosure.

FIGS. 19, 20, 21, 22, and 23 are cross-sectional views illustrating an example of a method of manufacturing the display device of FIGS. 4 and 18 according to one or more embodiments of the present disclosure.

FIG. 24 is a cross-sectional view taken along the line III-III′ of FIG. 3 according to one or more embodiments of the present disclosure.

FIG. 25 is a block diagram illustrating an electronic device according to one or more embodiments of present disclosure.

FIG. 26 is a schematic diagram of electronic devices according to one or more embodiments of the present disclosure.

### DETAILED DESCRIPTION

Hereinafter, example embodiments of the present disclosure will be described in more detail with reference to the accompanying drawings. In the drawings, the same reference numerals/characters are used for the same components in the drawings, and redundant descriptions of the same components will not be provided for conciseness.

In the present disclosure, a plane may be defined by a first direction D1 and a second direction D2 that intersects the first direction D1. For example, the first direction D1 and the second direction D2 may be normal (e.g., perpendicular) to each other. In addition, the term “a plan view” or “in a plan view” may refer to a state, in which it is viewed from a direction (e.g., a thickness direction) normal to the plane defined by the first direction D1 and the second direction D2. And the term “cross-sectional view” or “in a cross-sectional view” may refer to a state, in which it is viewed from the first direction D1 or the second direction D2.

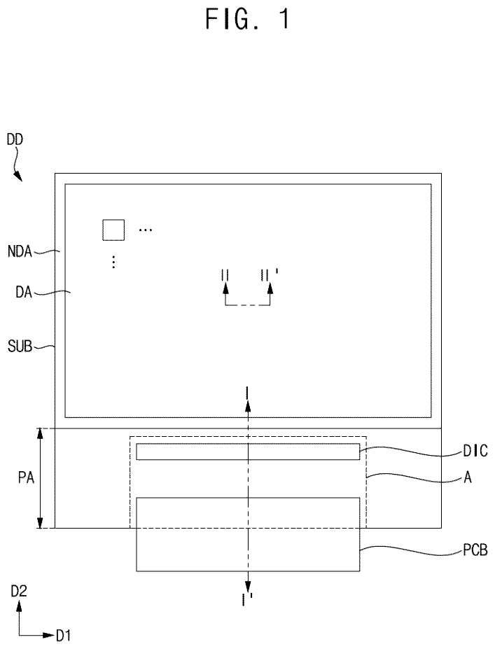

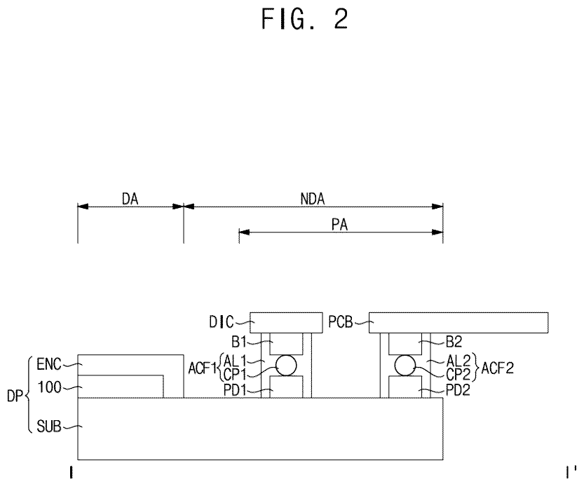

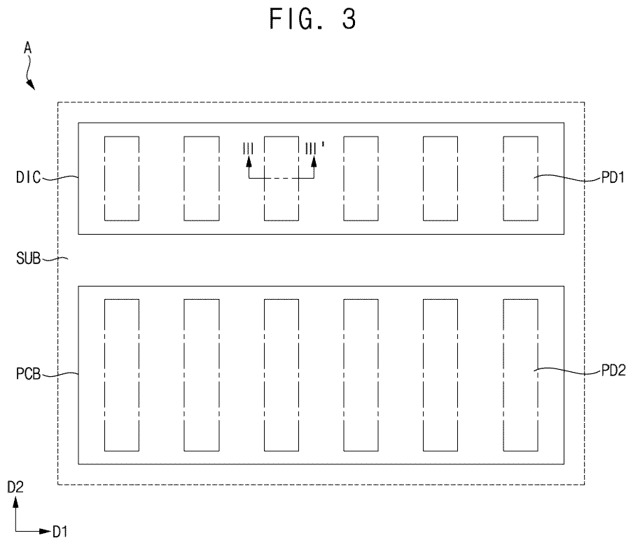

FIG. 1 is a plan view illustrating a display device according to one or more embodiments of the present disclosure. FIG. 2 is a cross-sectional view taken along the line I-I′ of FIG. 1 according to one or more embodiments. FIG. 3 is an enlarged plan view illustrating an area A of FIG. 1 according to one or more embodiments.

Referring to FIG. 1 and FIG. 2, a display device DD may include a display panel DP, a driving integrated circuit DIC, a circuit board PCB, and an anisotropic conductive film ACF.

The display panel DP may include a substrate SUB, a display part 100 located in a display area DA on the substrate SUB, and an encapsulation layer ENC located on the display part 100 and around (e.g., surrounding) the display part 100. A detailed description of the components of the display panel DP will be described in more detail later.

The substrate SUB may include the display area DA and a non-display area NDA.

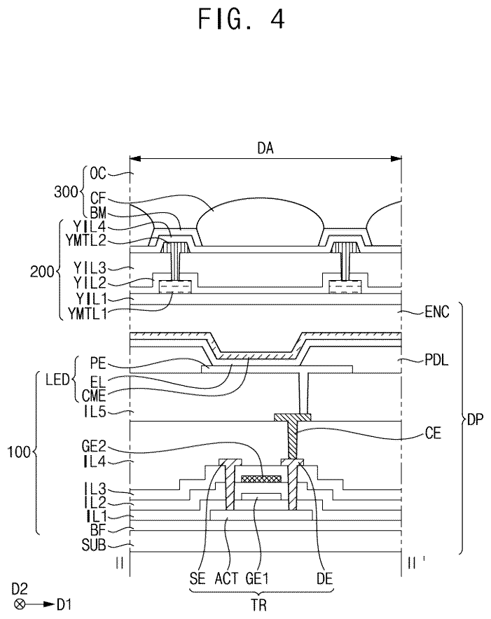

The display area DA may be an area that may display an image by generating light or adjusting the transmittance of light provided from an external light source. Additionally, a plurality of pixels PX may be located in the display area DA. Each of the plurality of pixels PX may be to emit light. Accordingly, an image may be displayed in the display area DA. The pixels PX may be located/arranged in a matrix form along a first direction D1 and a second direction D2 intersecting the first direction D1. Each pixel PX may include a light emitting element (e.g., a light emitting element LED illustrated in FIG. 4) and a pixel circuit for driving the light emitting element. In one or more embodiments, the light emitting element LED may include an organic light emitting diode, and the pixel circuit may include at least one thin film transistor. Wires connected to the plurality of pixels PX may be further located in the display area DA. For example, the wires may include data signal lines, gate signal lines, power lines, and/or the like.

The non-display area NDA may be an area that does not display images. Additionally, the non-display area NDA may be around (e.g., surround) at least a portion of the display area DA. For example, in one or more embodiments, the non-display area NDA may entirely be around (e.g., surround) the display area DA. Drivers for driving the pixels PX may be located in the non-display area NDA. For example, the drivers may include a gate driver, a light emitting driver, a power voltage generator, a timing controller, and/or the like. The plurality of the pixels PX may be to emit light based on signals received from the drivers.

Referring to FIG. 1, the non-display area NDA may include a pad area PA. For example, the pad area PA may be adjacent a lower part of the display area DA. The driving integrated circuit DIC and the circuit board PCB may be located in the pad area PA on the substrate SUB.

Referring to FIG. 3, a plurality of first pads PD1 and a plurality of second pads PD2 may be located in the pad area PA on the substrate SUB. The first pads PD1 and the second pads PD2 may each independently include metal, transparent conductive material, and/or the like. Examples of the transparent conductive material that may be used in the first pads PD1 and the second pads PD2 may include indium tin oxide (ITO), indium zinc oxide (IZO), indium zinc tin oxide (IZTO), and/or the like. These may be used alone or in combination with each other.

The first pads PD1 may be located to be spaced and/or apart (e.g., spaced apart or separated) from one another along the first direction D1, and the second pads PD2 may be located to be spaced and/or apart (e.g., spaced apart or separated) from one another along the first direction D1. In one or more embodiments, the first pads PD1 may be closer to the display area DA than the second pads PD2. For example, the first pads PD1 may be located between the display area DA and the second pads PD2 in a plan view.

The first pads PD1 may transfer voltage, control signals, and/or the like provided from the circuit board PCB to the driving integrated circuit DIC and provide voltage, control signals, and/or the like output from the driving integrated circuit DIC to the pixels PX. The second pads PD2 may provide voltage, control signals, and/or the like output from the circuit board PCB to the driving integrated circuit DIC.

Referring to FIG. 1 and FIG. 3, the driving integrated circuit DIC may be located in the pad area PA on the substrate SUB. For example, in one or more embodiments, there may be one driving integrated circuit DIC. However, embodiments of the present disclosure are not necessarily limited thereto. For example, in one or more embodiments, a plurality of driving integrated circuits DIC may be located at a lower end and an upper end of the non-display area NDA.

In one or more embodiments, if (e.g., when) the substrate SUB includes plastic, the driving integrated circuit DIC may have a chip on plastic (COP) structure located directly on the substrate SUB. However, embodiments of the present disclosure are not necessarily limited thereto. For example, in one or more embodiments, if (e.g., when) the substrate SUB includes glass, the driving integrated circuit DIC may have a chip on glass (COG) structure located directly on the substrate SUB.

Referring to FIG. 2, the driving integrated circuit DIC may include a plurality of first bumps B1. The first bumps B1 may correspondingly overlap the first pads PD1. The first bumps B1 may include metal. Non-limiting examples of the metal that may be used as the first bumps B1 may include gold (Au), silver (Ag), aluminum (Al), copper (Cu), and/or the like. These may be used alone or in combination with each other. Some of the first bumps B1 may receive voltage, control signals, and/or the like provided from the circuit board PCB, and others may output voltage, control signals, and/or the like provided to the pixels PX.

A first anisotropic conductive film ACF1 may be located in the pad area PA between the substrate SUB and the driving integrated circuit DIC. The first anisotropic conductive film ACF1 may bond the first pads PD1 and the respective first bumps B1. Accordingly, the first anisotropic conductive film ACF1 may electrically connect the substrate SUB and the driving integrated circuit DIC.

The first anisotropic conductive film ACF1 may include a first adhesive layer AL1 and a plurality of first conductive particles CP1 located in the first adhesive layer AL1.

The first adhesive layer AL1 may include an insulating polymer material. non-limiting examples of the insulating polymer material that may be used as the first adhesive layer AL1 may include epoxy resin, acrylic resin, phenol resin, melamine resin, diallyl phthalate resin, urea resin, polyimide resin, polystyrene resin, polyurethane resin, polyethylene resin, polyvinyl acetate resin, and/or the like. These may be used alone or in combination with each other.

The first conductive particles CP1 may be located between the first pads PD1 and the first bumps B1. Accordingly, the first conductive particles CP1 may electrically connect the substrate SUB and the driving integrated circuit DIC. In one or more embodiments, each of the first conductive particles CP1 may include a core including an insulating polymer material and a conductive film around (e.g., surrounding) the core and including a conductive metal material.

Referring to FIG. 1 and FIG. 3, the circuit board PCB may be located in the pad area PA on the substrate SUB. For example, the circuit board PCB may partially overlap the pad area PA. The circuit board PCB may provide voltage, control signals, and/or the like to the pixels PX. In one or more embodiments, if (e.g., when) the circuit board PCB is a flexible printed circuit board (FPCB), the circuit board PCB may have an FPCB on plastic (FOP) structure located directly on a plastic substrate. However, embodiments of the present disclosure are not necessarily limited thereto. For example, in one or more embodiments, if (e.g., when) the circuit board PCB is a flexible printed circuit board, the circuit board PCB may have an FPCB on glass (FOG) structure directly located on a glass substrate.

Referring to FIG. 2, the circuit board PCB may include a plurality of second bumps B2. The second bumps B2 may correspondingly overlap the second pads PD2. The second bumps B2 may include metal. Non-limiting examples of the metal that may be used as the second bumps B2 may include gold (Au), silver (Ag), aluminum (Al), copper (Cu), and/or the like. These may be used alone or in combination with each other. The second bumps B2 may provide voltage, control signals, and/or the like from the circuit board PCB to the second pads PD2.

A second anisotropic conductive film ACF2 may be located in the pad area PA between the substrate SUB and the circuit board PCB. The second anisotropic conductive film ACF2 may bond the second pads PD2 and the respective second bumps B2. Accordingly, the second anisotropic conductive film ACF2 may electrically connect the substrate SUB and the circuit board PCB.

The second anisotropic conductive film ACF2 may include a second adhesive layer AL2 and a plurality of second conductive particles CP2 located in the second adhesive layer AL2. The second conductive particles CP2 may be located between the second pads PD2 and the second bumps B2. Accordingly, the second conductive particles CP2 may electrically connect the substrate SUB and the circuit board PCB.

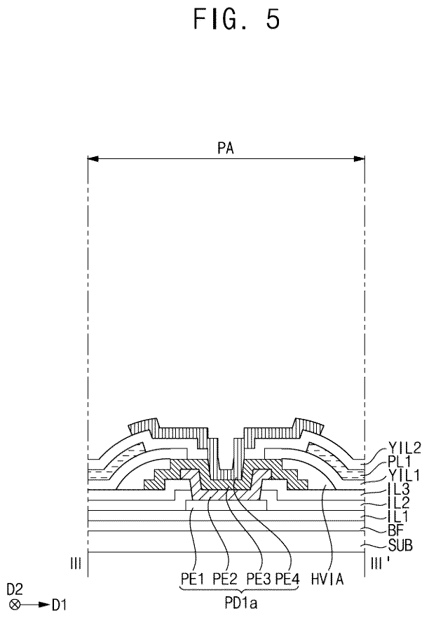

FIG. 4 is a cross-sectional view taken along the line II-II′ of FIG. 1 according to one or more embodiments of the present disclosure. FIG. 5 is a cross-sectional view of taken along the line III-III′ of FIG. 3 according to one or more embodiments of the present disclosure.

Referring to FIG. 4 and FIG. 5, the display device DD according to one or more embodiments of the present disclosure may include the substrate SUB, the display part 100, the encapsulation layer ENC, a touch layer 200, an anti-reflection layer 300, a first pad PD1a, an insulating layer HVIA and an anti-etching layer PL1.

The display part 100 may include a buffer layer BF, a transistor TR, a second gate electrode GE2, first, second, third, fourth, and fifth insulating layers IL1, IL2, IL3, IL4, and IL5, a connection electrode CE, a light emitting element LED, and a pixel defining layer PDL.

The transistor TR may include an active pattern ACT, a first gate electrode GE1, a source electrode SE, and a drain electrode DE. The light emitting element LED may include a pixel electrode PE, a light emitting layer EL, and a common electrode CME. The touch layer 200 may include first, second, third, and fourth touch insulating layers YIL1, YIL2, YIL3, and YIL4, a first touch electrode YMTL1, and a second touch electrode YMTL2. The anti-reflection layer 300 may include a black matrix BM, a color filter CF, and an overcoat layer OC. The first pad PD1a may include first, second, third, and fourth pad electrodes PE1, PE2, PE3, and PE4.

The substrate SUB may include glass, quartz, silicon, plastic (e.g., a polymer material), and/or the like. Non-limiting examples of the plastic that may be used for the substrate SUB may include polyimide (PI), polyethylene terephthalate (PET), polyethylene naphthalene (PEN), polypropylene (PP), polycarbonate (PC), polystyrene (PS), polysulfone (PSul), polyethylene (PE), polyphthalamide (PPA), polyethersulfone (PES), polyarylate (PAR), polycarbonate oxide (PCO), modified polyphenylene oxide (MPPO), and/or the like. These may be used alone or in combination with each other.

The buffer layer BF may be located on the substrate SUB. The buffer layer BF may prevent or reduce impurities such as oxygen and moisture from being diffused to the top of the substrate SUB through the substrate SUB, and may planarize an upper surface of the substrate SUB. In one or more embodiments, the buffer layer BF may include an inorganic insulating material such as silicon compound, metal oxide, and/or the like. For example, in one or more embodiments, the buffer layer BF may include silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), and/or the like. These may be used alone or in combination with each other.

The active pattern ACT may be located in the display area DA on the buffer layer BF. For example, in one or more embodiments, the active pattern ACT may include a silicon semiconductor such as amorphous silicon, polycrystalline silicon, and/or the like. In one or more embodiments, the active pattern ACT may include a metal oxide semiconductor. The active pattern ACT may have a source region, a drain region, and a channel region located between the source region and the drain region.

The first insulating layer IL1 may be located on the buffer layer BF. For example, the first insulating layer IL1 may cover the active pattern ACT and may be located along a profile of the active pattern ACT with a substantially uniform thickness. The first insulating layer IL1 may insulate the channel region of the active pattern ACT and the first gate electrode GE1 located on the first insulating layer IL1. For example, the first insulating layer IL1 may include one or more of the aforementioned inorganic insulating materials. These inorganic insulating materials may be used alone or in combination with each other.

The first gate electrode GE1 may be located in the display area DA on the first insulating layer IL1. The first gate electrode GE1 may overlap the channel region of the active pattern ACT. In one or more embodiments, the first gate electrode GE1 may include a conductive material such as a metal, a metal alloy, a conductive metal nitride, a conductive metal oxide, a transparent conductive material, and/or the like. For example, the first gate electrode GE1 may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing aluminum, an alloy containing silver, an alloy containing copper, an alloy containing molybdenum, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), and/or the like. These may be used alone or in combination with each other.

The first pad electrode PE1 may be located in the pad area PA on the first insulating layer IL1. In one or more embodiments, the first pad electrode PE1 may include a same material as the first gate electrode GE1. For example, the first pad electrode PE1 may be formed through a same process as the first gate electrode GE1.

The second insulating layer IL2 may be located on the first insulating layer IL1. The second insulating layer IL2 may cover the first gate electrode GE1, and may be located along a profile of the first gate electrode GE1 with a substantially uniform thickness. Additionally, the second insulating layer IL2 may cover an edge of the fist pad electrode PE1 in the pad area PA and may expose an upper surface of the first pad electrode PE1. For example, the second insulating layer IL2 may include one or more inorganic insulating materials described herein. These inorganic insulating materials may be used alone or in combination with each other.

The second gate electrode GE2 may be located in the display area DA on the second insulating layer IL2. The second gate electrode GE2 may overlap the first gate electrode GE1 in a plan view. The second gate electrode GE2 may include one or more conductive materials described herein. These may be used alone or in combination with each other. In one or more embodiments, the first gate electrode GE1 and the second gate electrode GE2 may form a capacitor.

The third insulating layer IL3 may be located on the second insulating layer IL2. The third insulating layer IL3 may cover the second gate electrode GE2, and may be located along a profile of the second gate electrode GE2 with a substantially uniform thickness. Additionally, the third insulating layer IL3 may cover an edge of the second insulating layer IL2 in the pad area PA, and may expose the upper surface of the first pad electrode PE1. For example, the third insulating layer IL3 may include one or more inorganic insulating materials described herein. Theses inorganic insulating materials may be used alone or in combination with each other.

The source electrode SE and the drain electrode DE may be located in the display area DA on the third insulating layer IL3. The source electrode SE may be connected to the source region of the active pattern ACT through a contact hole penetrating the first, second, and third insulating layers IL1, IL2, and IL3, and the drain electrode DE may be connected to the drain region of the active pattern ACT through a contact hole penetrating the first, second, and third insulating layers IL1, IL2, and IL3. Each of the source electrode SE and the drain electrode DE may include a conductive material described herein. These conductive materials may be used alone or in combination with each other.

Accordingly, the transistor TR including the active pattern ACT, the first gate electrode GE1, the source electrode SE, and the drain electrode DE may be located in the display area DA.

The second pad electrode PE2 may be located in the pad area PA on the third insulating layer IL3. For example, the second pad electrode PE2 may directly contact the exposed upper surface of the first pad electrode PE1. The second pad electrode PE2 may extend along side surfaces of the second and third insulating layers IL2 and IL3 to a portion of an upper surface of the third insulating layer IL3. In one or more embodiments, the second pad electrode PE2 may include a same material as the source electrode SE and the drain electrode DE. For example, the second pad electrode PE2 may be formed through a same process as the source electrode SE and the drain electrode DE.

The fourth insulating layer IL4 may be located on the third insulating layer IL3. The fourth insulating layer IL4 may sufficiently cover the source electrode SE and the drain electrode DE. For example, the fourth insulating layer IL4 may include an organic insulating material (e.g., a polymer material/resin described herein). The organic insulating materials may be used alone or in combination with each other.

The connection electrode CE may be located on the fourth insulating layer IL4. The connection electrode CE may be connected to the drain electrode DE through a contact hole penetrating the fourth insulating layer IL4. Accordingly, the connection electrode CE may electrically connect the transistor TR and the light emitting element LED. For example, the connection electrode CE may include a conductive material described herein. These conductive materials may be used alone or in combination with each other.

The third pad electrode PE3 may be located in the pad area PA on the second pad electrode PE2. For example, the third pad electrode PE3 may directly contact the second pad electrode PE2. The third pad electrode PE3 may be located to completely cover the second pad electrode PE2. In one or more embodiments, the third pad electrode PE3 may include a same material as the connection electrode CE. For example, the third pad electrode PE3 may be formed through a same process as the connection electrode CE.

The fifth insulating layer IL5 may be located on the fourth insulating layer IL4. The fifth insulating layer IL5 may have a substantially flat upper surface. For example, in one or more embodiments, the fifth insulating layer IL5 may include an organic insulating material (e.g., a polymer material/resin described herein). The organic insulating materials may be used alone or in combination with each other.

The insulating layer HVIA may be located in the pad area PA on the third insulating layer IL3. The insulating layer HVIA may cover an edge of the third pad electrode PE3. For example, in one or more embodiments, the insulating layer HVIA may cover a tip formed when the third pad electrode PE3 includes a plurality of conductive layers so that the tip is not exposed to the outside. Accordingly, short circuit defect may be prevented. In one or more embodiments, the insulating layer HVIA may include a same material as the fifth insulating layer IL5. For example, the insulating layer HVIA may be formed through a same process as the fifth insulating layer IL5.

The pixel electrode PE may be located in the display area DA on the fifth insulating layer IL5. The pixel electrode PE may be connected to the connection electrode CE through a contact hole penetrating the fifth insulating layer IL5. Accordingly, the pixel electrode PE may be electrically connected to the transistor TR. For example, the pixel electrode PE may include a conductive material described herein. These conductive materials may be used alone or in combination with each other. In one or more embodiments, the pixel electrode PE may function as an anode.

The pixel defining layer PDL may be located on the fifth insulating layer IL5. The pixel defining layer PDL may cover an edge of the pixel electrode PE, and may define a pixel opening that exposes a center of the pixel electrode PE. A light emitting area may be defined by the pixel opening. The pixel defining layer PDL may include an inorganic material or an organic material. In one or more embodiments, the pixel defining layer PDL may include an organic material such as an epoxy resin, a siloxane resin, and/or the like. These may be used alone or in combination with each other. In one or more embodiments, the pixel defining layer PDL may further include a black-colored light blocking material.

The light emitting layer EL may be located on the pixel electrode PE and the pixel defining layer PDL. A portion of the light emitting layer EL may be located in the pixel opening of the pixel defining layer PDL. In one or more embodiments, the light emitting layer EL may include a first functional layer including an organic material, a middle layer located on the first functional layer and including a light emitting material, and a second functional layer located on the middle layer and including an organic material. For example, the first functional layer may include a hole injection layer, a hole transport layer, and/or the like, and the second functional layer may include an electron transport layer, an electron injection layer, and/or the like. For example, the middle layer may include a light emitting material that emits at least one of red light, green light, or blue light.

The common electrode CME may be located on the light emitting layer EL. The common electrode CME may continuously extend on the display area DA across the plurality of pixels PX. For example, the common electrode CME may include a conductive material described herein. These conductive materials may be used alone or in combination with each other. In one or more embodiments, the common electrode CME may function as a cathode.

Accordingly, the light emitting element LED including the pixel electrode PE, the light emitting layer EL, and the common electrode CME may be located in the display area DA.

The encapsulation layer ENC may be located on the common electrode CME. The encapsulation layer ENC may prevent or reduce impurities, moisture, and/or the like from penetrating into the light emitting element LED from the outside. The encapsulation layer ENC may include at least one inorganic layer and one organic layer. For example, the inorganic layer may include silicon oxide (SiOₓ), silicon nitride (SiNₓ), silicon oxynitride (SiOₓN_{y}), and/or the like. These materials may be used alone or in combination with each other. The organic layer may include a cured polymer such as polyacrylate, and/or the like.

The first touch insulating layer YIL1 may be located on the encapsulation layer ENC. For example, the first touch insulating layer YIL1 may include an inorganic insulating material described herein. These inorganic materials may be used alone or in combination with each other.

The first touch insulating layer YIL1 may extend from the display area DA to the pad area PA. The first touch insulating layer YIL1 may located on the third pad electrode PE3 and the insulating layer HVIA in the pad area PA. For example, in one or more embodiments, the first touch insulating layer YIL1 may be located to cover a portion of an upper surface of the third pad electrode PE3 and completely cover the insulating layer HVIA. The first touch insulating layer YIL1 may suppress or reduce moisture permeation into the insulating layer HVIA and corrosion of the first pad PD1a. Accordingly, defects in the display device DD caused by moisture permeation may be prevented or reduced.

The first touch electrode YMTL1 may be located in the display area DA on the first touch insulating layer YIL1. For example, the fist touch electrode YMTL1 may include a conductive material described herein. These conductive materials may be used alone or in combination with each other.

The anti-etching layer PL1 may be located in the pad area PA on the first touch insulating layer YIL1. For example, the anti-etching layer PL1 may be located between the first touch insulating layer YIL1 and the second touch insulating layer YIL2. The anti-etching layer PL1 may directly contact an upper surface of the first touch insulating layer YIL1 and a lower surface of the second touch insulating layer YIL2. An edge of the anti-etching layer PL1 may at least partially overlap an edge of the fourth pad electrode PE4 in a plan view. In one or more embodiments, the anti-etching layer PL1 may include a same material as the first touch electrode YMTL1. For example, the anti-etching layer PL1 may be formed through a same process as the first touch electrode YMTL1.

The anti-etching layer PL1 may prevent or reduce the first touch insulating layer YIL1 from being removed when the fourth pad electrode PE4 is etched. For example, during the compression process to attach the driving integrated circuit DIC and the circuit board PCB onto the substrate SUB, cracks may be prevented or reduced from occurring in the first touch insulating layer YIL1 in the pad area PA, and corrosion of the first pad PD1a due to moisture permeation into the insulating layer HVIA through the cracks may be suppressed or reduced. Accordingly, it may prevent or reduce or reduce defects in the display device DD due to moisture permeation.

The second touch insulating layer YIL2 may be located in the display area DA on the first touch insulating layer YIL1. The second touch insulating layer YIL2 may cover the first touch electrode YMTL1, and may be located along a profile of the first touch electrode YMTL1 with a substantially uniform thickness. For example, the second touch insulating layer YIL2 may include an inorganic insulating material described herein. These inorganic insulating materials may be used alone or in combination with each other.

The second touch insulating layer YIL2 may extend from the display area DA to the pad area PA. the second touch insulating layer YIL2 may be located on the first touch insulating layer YIL1 and the anti-etching layer PL1 in the pad area PA. For example, the second touch insulating layer YIL2 may cover the first touch insulating layer YIL1 and the anti-etching layer PL1, and may be located to a portion of an upper surface of the third pad electrode PE3 along the profiles of the first touch insulating layer YIL1 and the anti-etching layer PL1 with a substantially uniform thickness. Accordingly, a lower surface of the second touch insulating layer YIL2 may contact the upper surfaces of the third pad electrode PE3, the first touch insulating layer YIL1, and the anti-etching layer PL1. In one or more embodiments, the second touch insulating layer YIL2 may cover an end of the first touch insulating layer YIL1. Additionally, an opening exposing the third pad electrode PE3 may be defined in the second touch insulating layer YIL2.

In the pad area PA, the second touch insulating layer YIL2, together with the first touch insulating layer YIL1, may form an inorganic layer of sufficient thickness to resist external pressure. For example, during the compression process to attach the driving integrated circuit DIC and the circuit board PCB onto the substrate SUB, cracks may be prevented or reduced from occurring in the first touch insulating layer YIL1 in the pad area PA, and corrosion of the first pad PD1a due to moisture permeation into the insulating layer HVIA through the cracks may be suppressed or reduced. Accordingly, it may prevent or reduce defects in the display device DD due to moisture permeation.

The third touch insulating layer YIL3 may be located in the display area DA on the second touch insulating layer YIL2. The third touch insulating layer YIL3 may sufficiently cover the second touch insulating layer YIL2, and may have a substantially flat upper surface without generating a step around the second touch insulating layer YIL2. For example, the third touch insulating layer YIL3 may include an organic insulating material (e.g., a polymer material/resin described herein). The organic insulating materials may be used alone or in combination with each other.

The second touch electrode YMTL2 may be located on the third touch insulating layer YIL3. The second touch electrode YMTL2 may be connected to the first touch electrode YMTL1 through a contact hole penetrating the second touch insulating layer YIL2 and the third touch insulating layer YIL3. The first touch electrode YMTL1 and the second touch electrode YMTL2 may detect an external touch and may transmit a signal to a touch driver. For example, the second touch electrode YMTL2 may include a conductive material described herein. These conductive materials may be used alone or in combination with each other.

The fourth pad electrode PE4 may be located on the third pad electrode PE3. For example, the fourth pad electrode PE4 may cover the third pad electrode PE3 and a portion of the second touch insulating layer YIL2, and may be located along the profiles of the third pad electrode PE3 and the portion of the second touch insulating layer YIL2 with a substantially uniform thickness. Accordingly, a lower surface of the fourth pad electrode PE4 may directly contact the third pad electrode PE3 and the second touch insulating layer YIL2. The fourth pad electrode PE4 may overlap the opening exposing the third pad electrode PE3 defined in the second touch insulating layer YIL2. The fourth pad electrode PE4 may be located to be spaced and/or apart (e.g., spaced apart or separated) from the first touch insulating layer YIL1. Additionally, the fourth pad electrode PE4 may include a same material as the second touch electrode YMTL2. For example, the fourth pad electrode PE4 may be formed through a same process as the second touch electrode YMTL2.

The fourth touch insulating layer YIL4 may be located on the third touch insulating layer YIL3 and the second touch electrode YMTL2. The fourth touch insulating layer YIL4 may cover the second touch electrode YMTL2, and may be located along the profile of the second touch electrode YMTL2 with a substantially uniform thickness. For example, the fourth touch insulating layer YIL4 may include an inorganic insulating material described hereon. These inorganic insulating materials may be used alone or in combination with each other.

The black matrix BM may be located in the display area DA on the fourth touch insulating layer YIL4. For example, the black matrix BM may overlap the pixel defining layer PDL in a plan view. For example, black matrix BM may include a light blocking material. An opening exposing at least a portion of the fourth touch insulating layer YIL4 may be defined in the black matrix BM.

The color filter CF may be located on the fourth touch insulating layer YIL4 and the black matrix BM. For example, the color filter CF may be located in the opening of the black matrix BM. The color filter CF may be a red color filter that transmits red light, a green color filter that transmits green light, or a blue color filter that transmits blue light.

The overcoat layer OC may be located on the color filter CF and the black matrix BM. The overcoat layer OC may have a substantially flat upper surface. For example, the overcoat layer OC may include an organic material such as an acrylic resin, and/or the like. Accordingly, reflection of external light may be prevented or reduced through the anti-reflection layer 300 including the black matrix BM, the color filter CF, and the overcoat layer OC.

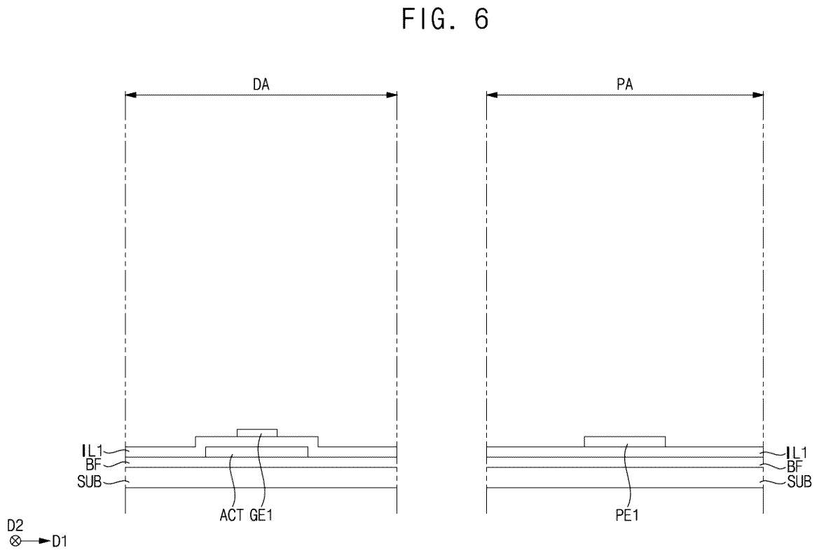

FIGS. 6, 7, 8, 9, 10, 11, 12, 13, 14, 15, and 16 are cross-sectional views illustrating an example of a method of manufacturing the display device of FIGS. 4 and 5 according to one or more embodiments of the present disclosure.

Referring to FIG. 6, the buffer layer BF may be formed on the substrate SUB. The active pattern ACT may be formed in the display area DA on the buffer layer BF. For example, the active pattern ACT may be formed using an inorganic semiconductor.

The first insulating layer IL1 may be formed on the buffer layer BF. The first insulating layer IL1 may be formed in the display area DA and the pad area PA. For example, the first insulating layer IL1 may be formed using an inorganic material (e.g., an inorganic insulating material).

The first gate electrode GE1 may be formed in the display area DA on the first insulating layer IL1. The first gate electrode GE1 may overlap the channel region of the active pattern ACT. For example, the first gate electrode GE1 may be formed using a conductive material.

The first pad electrode PE1 may be formed in the pad area PA on the first insulating layer IL1. The first pad electrode PE1 may be concurrently (e.g., simultaneously) formed through the same process as the first gate electrode GE1.

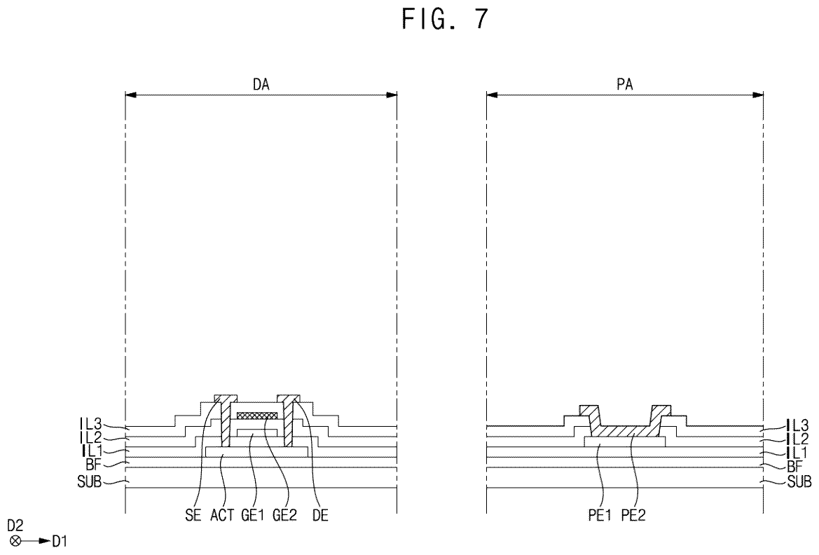

Referring to FIG. 7, the second insulating layer IL2 may be formed on the first insulating layer IL1. After the second insulating layer IL2 is entirely formed in the display area DA and the pad area PA, a portion of the second insulating layer IL2 located in the pad area PA may be removed through an etching process. The second insulating layer IL2 may cover an edge of the first pad electrode PE1 in the pad area PA, and may expose an upper surface of the first pad electrode PE1. For example, the second insulating layer IL2 may be formed using an inorganic insulating material.

The second gate electrode GE2 may be formed in the display area DA on the second insulating layer IL2. The second gate electrode GE2 may overlap the first gate electrode GE1. For example, the second gate electrode GE2 may be formed using a conductive material.

The third insulating layer IL3 may be formed on the second insulating layer IL2. After the third insulating layer IL3 is entirely formed in the display area DA and the pad area PA, a portion of the third insulating layer IL3 located in the pad area PA may be removed through an etching process. Accordingly, the third insulating layer IL3 may cover an edge of the second insulating layer IL2 in the pad area PA, and may expose the upper surface of the first pad electrode PE1. For example, the third insulating layer IL3 may be formed using an inorganic insulating material.

The source electrode SE and the drain electrode DE may be formed in the display area DA on the third insulating layer IL3. The source electrode SE may be connected to the source region of the active pattern ACT through a contact hole penetrating the first, second, and third insulating layers IL1, IL2, and IL3. The drain electrode DE may be connected to the drain region of the active pattern ACT through a contact hole penetrating the first, second, and third insulating layers IL1, IL2, and IL3. For example, the source electrode SE and the drain electrode DE may include a conductive material.

The second pad electrode PE2 may be formed on the first pad electrode PE1. For example, the second pad electrode PE2 may be formed to directly contact the upper surface of the first pad electrode PE1 exposed by the second and third insulating layers IL2 and IL3 in the pad area PA. The second pad electrode PE2 may be concurrently (e.g., simultaneously) formed through the same process as the source electrode SE and the drain electrode DE.

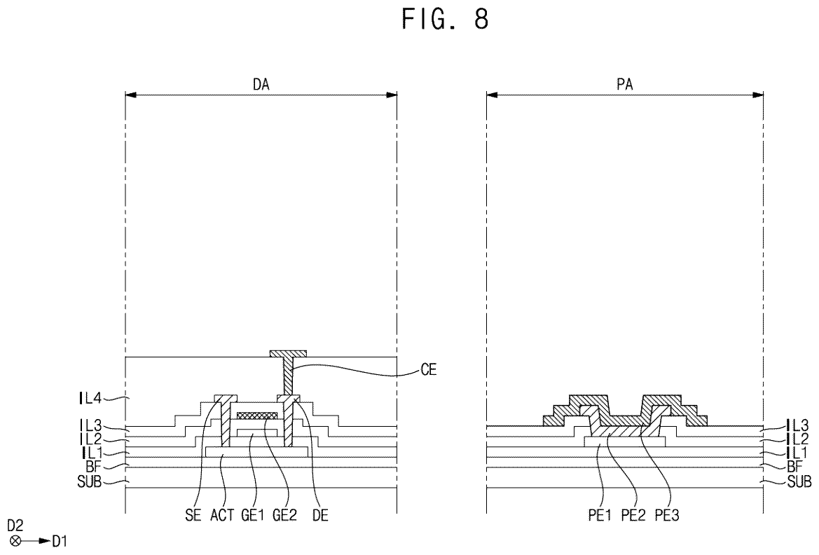

Referring to FIG. 8, the fourth insulating layer IL4 may be formed in the display area DA on the third insulating layer IL3. The fourth insulating layer IL4 may cover the source electrode SE and the drain electrode DE. For example, the fourth insulating layer IL4 may be formed using an organic insulating material (e.g., a polymer material/resin described herein).

The connection electrode CE may be formed on the fourth insulating layer IL4. The connection electrode CE may be connected to the drain electrode DE through a contact hole penetrating the fourth insulating layer IL4. For example, the connection electrode CE may be formed using a conductive material.

The third pad electrode PE3 may be formed on the second pad electrode PE2. The third pad electrode PE3 may be formed to directly contact the second pad electrode PE2 and completely cover the second pad electrode PE2. The third pad electrode PE3 may be concurrently (e.g., simultaneously) formed through the same process as the connection electrode CE.

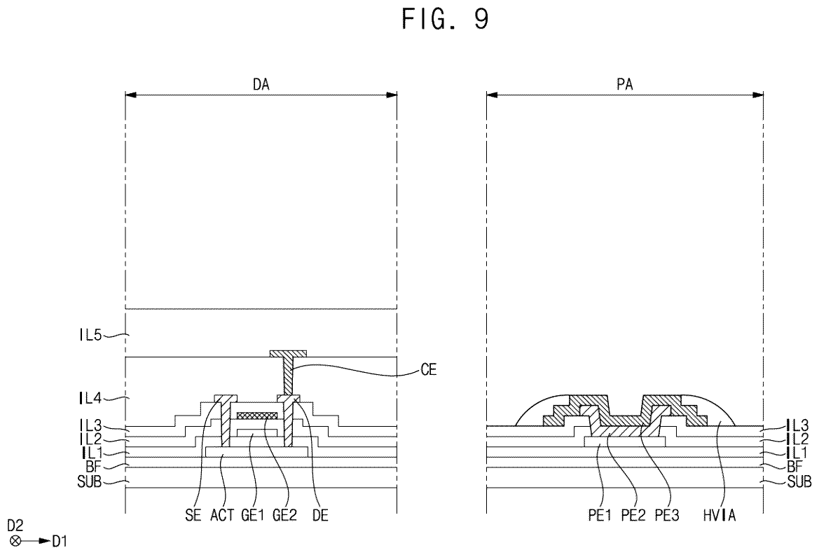

Referring to FIG. 9, the fifth insulating layer IL5 may be formed on the fourth insulating layer IL4. The fifth insulating layer IL5 may cover the connection electrode CE in the display area DA. For example, the fifth insulating layer IL5 may be formed using an organic insulating material (e.g., a polymer material/resin described herein).

The insulating layer HVIA may be formed in the pad area PA on the third insulating layer IL3. The insulating layer HVIA may be formed to cover an edge of the third pad electrode PE3. The insulating layer HVIA may be formed using the same material as the fifth insulating layer IL5. For example, after the fifth insulating layer IL5 is entirely formed in the display area DA and the pad area PA, a portion of the fifth insulating layer IL5 located in the pad area PA is removed, so that the insulating layer HVIA may be formed in the pad area PA.

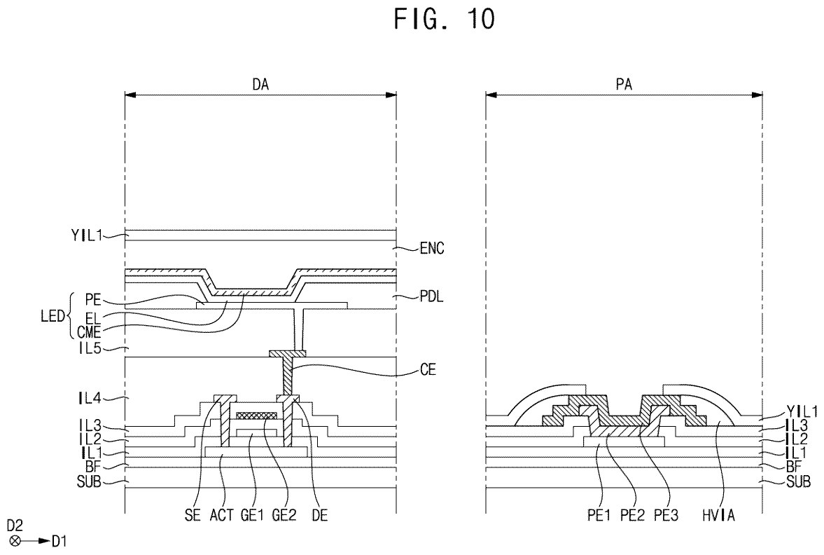

Referring to FIG. 10, the pixel electrode PE may be formed in the display area DA on the fifth insulating layer IL5. The pixel electrode PE may be connected to the connection electrode CE through a contact hole penetrating the fifth insulating layer IL5. For example, the pixel electrode PE may be formed using a conductive material.

The pixel defining layer PDL may be formed on the fifth insulating layer IL5. The pixel defining layer PDL may cover an edge of the pixel electrode PE. For example, the pixel defining layer PDL may be formed using an organic material containing a light blocking material.

The light emitting layer EL may be formed on the pixel electrode PE. The light emitting layer EL may be formed using an organic material that emits light of a preset color.

The common electrode CME may be formed on the pixel defining layer PDL and the light emitting layer EL. For example, the common electrode CME may be formed using a conductive material.

The encapsulation layer ENC may be formed on the common electrode CME. The encapsulation layer ENC may include at least one inorganic layer and at least one organic layer.

The first touch insulating layer YIL1 may be formed in the display area DA on the encapsulation layer ENC. Additionally, the fist touch insulating layer YIL1 may be formed on the third touch insulating layer IL3, the insulating layer HVIA, and the third pad electrode PE3 in the pad area PA. For example, after the first touch insulating layer YIL1 is entirely formed in the display area DA and the pad area PA, a portion of the first touch insulating layer YIL1 located in the pad area PA is removed, so that an upper surface of the third pad electrode PE3 may be exposed. For example, the first touch insulating layer YIL1 may be formed using an inorganic insulating material.

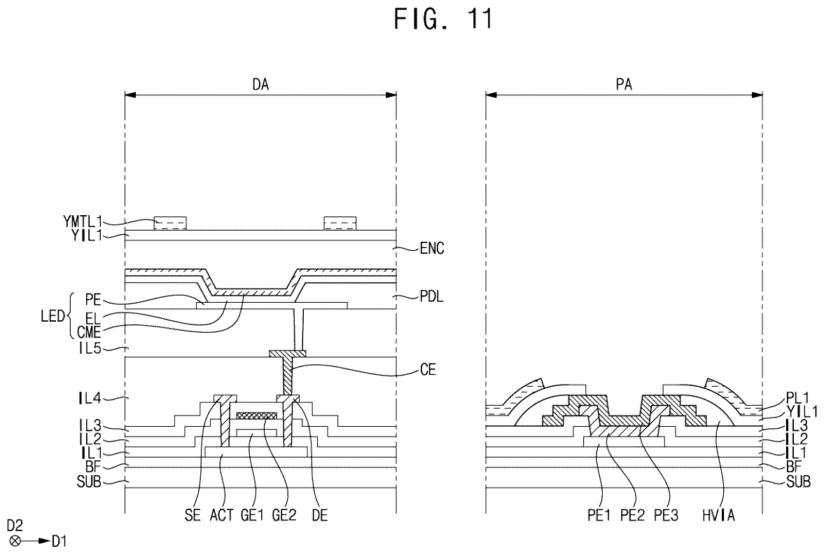

Referring to FIG. 11, the first touch electrode YMTL1 may be formed in the display area DA on the first touch insulating layer YIL1. For example, the first touch electrode YMTL1 may be formed using a conductive material.

The anti-etching layer PL1 may be formed in the pad area PA on the first touch insulating layer YIL1. In one or more embodiments, the anti-etching layer PL1 may be formed using the same material as the first touch electrode YMTL1. For example, the anti-etching layer PL1 may be concurrently (e.g., simultaneously) formed through the same process as the first touch electrode YMTL1. For example, a first touch electrode layer may be entirely formed in the display area DA and the pad area PA. The first touch electrode YMTL1 may be formed by removing a portion of the first touch electrode layer in the display area DA. At the same time, for example, concurrently, the anti-etching layer PL1 may be formed by removing a portion of the first touch electrode layer in the pad area PA. Accordingly, the opening exposing the upper surface of the third pad electrode PE3 may be formed.

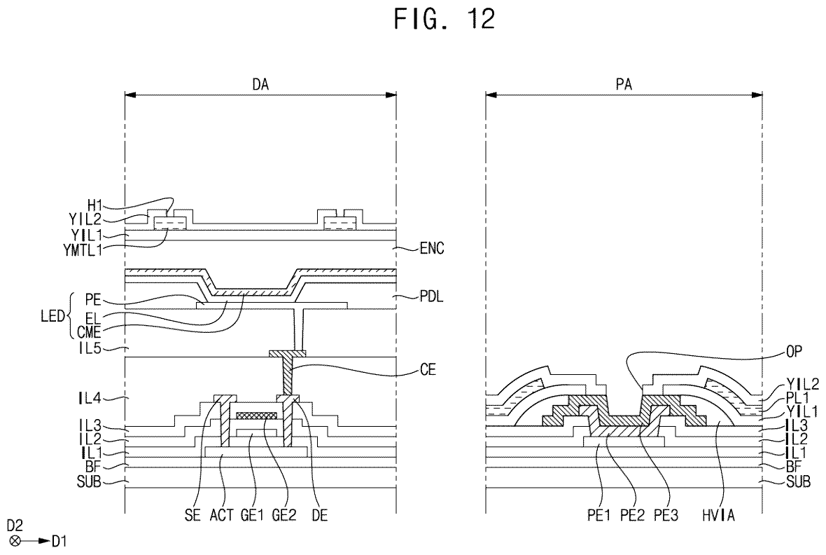

Referring to FIG. 12, the second touch insulating layer YIL2 may be formed in the display area DA on the first touch insulating layer YIL1 and in the pad area PA on the first touch insulating layer YIL1 and the anti-etching layer PL1. For example, the second touch insulating layer YIL2 may be formed using an inorganic insulating material. For example, the second touch insulating layer YIL2 may be entirely formed in the display area DA and the pad area PA. A first contact hole H1 exposing a portion of an upper surface of the first touch electrode YMTL1 may be formed by removing a portion of the second touch insulating layer YIL2 located in the display area DA through an etching process. Additionally, an opening OP exposing the upper surface of the third pad electrode PE3 may be formed by removing a portion of the second touch insulating layer YIL2 located in the pad area PA through the etching process.

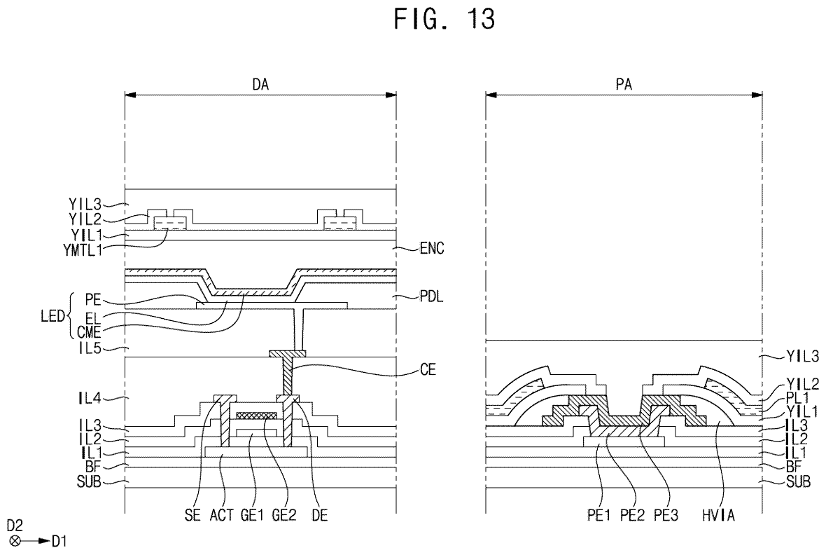

Referring to FIG. 13, the third touch insulating layer YIL3 may be entirely formed in the display area DA and the pad area PA on the second touch insulating layer YIL2. For example, the third touch insulating layer YIL3 may be formed using an organic insulating material.

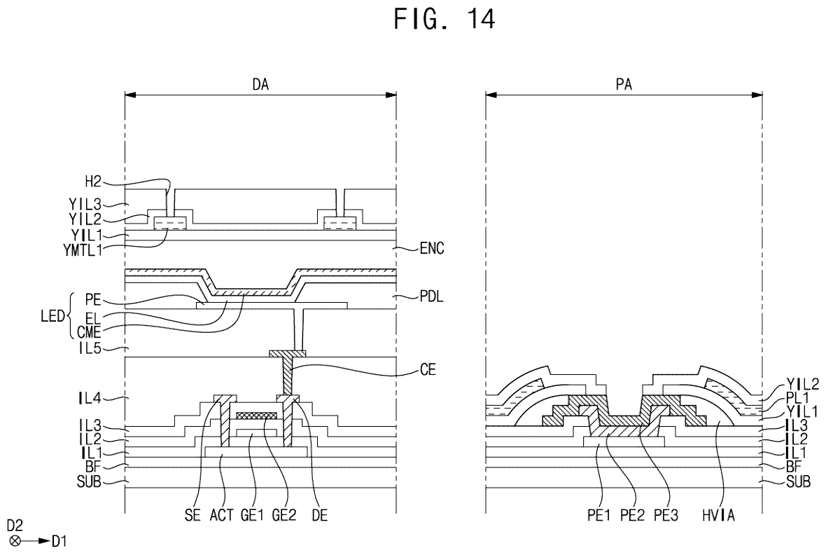

Referring to FIG. 14, a second contact hole H2 may be formed in the third touch insulating layer YIL3 in the display area DA, and the third touch insulating layer YIL3 may be completely removed in the pad area PA. For example, the third touch insulating layer YIL3 may be used as a photoresist (PR). For example, the third touch insulating layer YIL3 may include a positive photoresist or a negative photoresist.

The second contact hole H2 that overlaps the first contact hole H1 and exposes the first touch electrode YMTL1 may be formed in the display area DA on third touch insulating layer YIL3 by placing a mask on the third touch insulating layer YIL3 and exposing and developing the third touch insulating layer YIL3 through the mask. At the same time, the upper surface of the third pad electrode PE3 may be exposed by removing the entire third touch insulating layer YIL3 in the pad area PA.

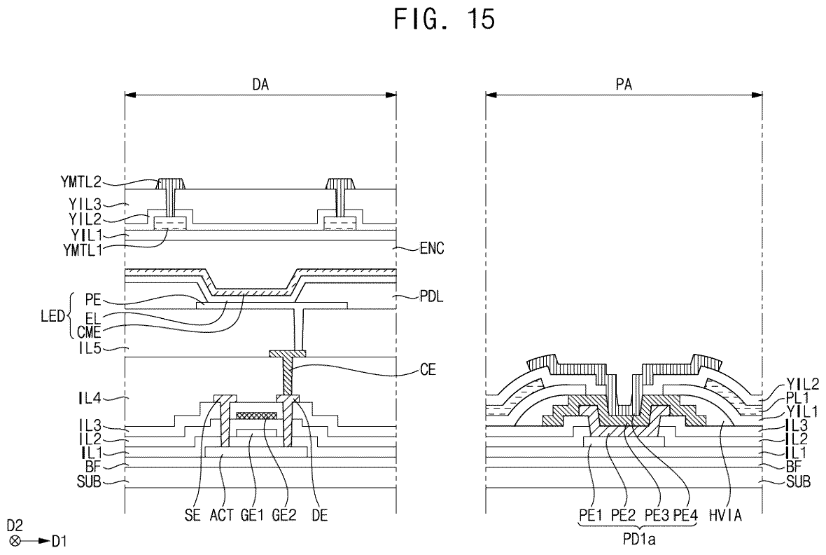

Referring to FIG. 15, the second touch electrode YMTL2 may be formed in the display area DA on the third touch insulating layer YIL3. The second touch electrode YMTL2 may be connected to the first touch electrode YMTL1 through the second contact hole H2 (see FIG. 14). For example, the second touch electrode YMTL2 may be formed using a conductive material.

The fourth pad electrode PE4 may be formed in the pad area PA on the third pad electrode PE3 and the second touch insulating layer YIL2. The fourth pad electrode PE4 may be formed using the same material as the second touch electrode YMTL2. For example, the fourth pad electrode PE4 may be concurrently (e.g., simultaneously) formed through the same process as the second touch electrode YMTL2. For example, a second touch electrode layer may be entirely formed in the display area DA and the pad area PA. The second touch electrode YMTL2 may be formed by etching the second touch electrode layer in the display area DA. At the same time, the fourth pad electrode PE4 may be formed by etching the second touch electrode layer in the pad area PA.

The fourth pad electrode PE4 may be formed to directly contact the third pad electrode PE3 and the second touch insulating layer YIL2. The fourth pad electrode PE4 may be formed in the opening OP (see FIG. 12). An edge of the fourth pad electrode PE4 may be formed to at least partially overlap an edge of the anti-etching layer PL1 in a plan view. The first to fourth pad electrodes PE1, PE2, PE3, and PE4 constitute the first pad PD1a.

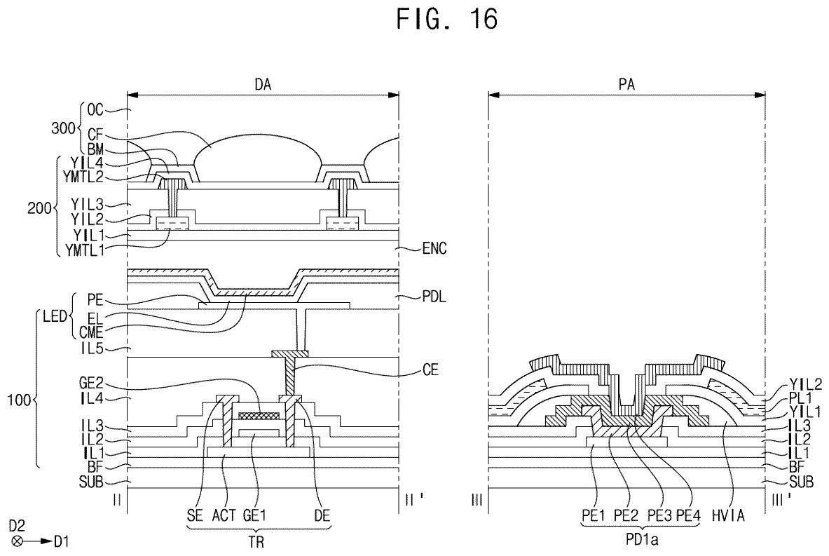

Referring to FIG. 16, the fourth touch insulating layer YIL4 may be formed on the third touch insulating layer YIL3 in the display area DA. For example, the fourth touch insulating layer YIL4 may be formed using an inorganic insulating material.

The black matrix BM may be formed on the fourth touch insulating layer YIL4. The black matrix BM may be formed to overlap the pixel defining layer PDL in a plan view. For example, the black matrix BM may be formed using a light blocking material. An opening exposing at least the portion of the fourth touch insulating layer YIL4 may be formed in the black matrix BM.

The color filter CF may be formed on the fourth touch insulating layer YIL4 and the black matrix BM. For example, the color filter CF may be formed in the opening of the black matrix BM.

The overcoat layer OC may be formed on the color filter CF and the black matrix BM. For example, the overcoat layer OC may be formed using an organic material such as an acrylic resin, and/or the like.

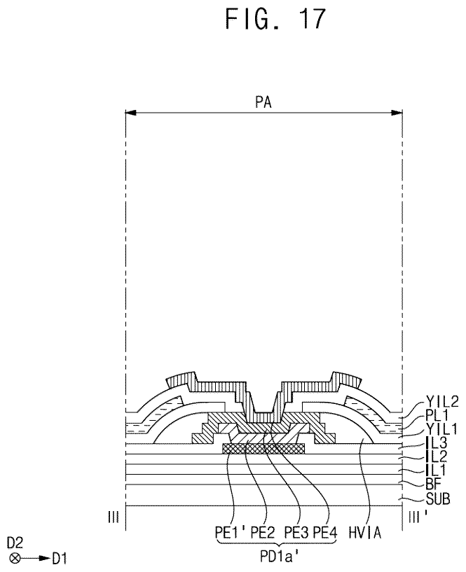

FIG. 17 is a cross-sectional view taken along the line III-III′ of FIG. 3 according to one or more embodiments of the present disclosure. Hereinafter, descriptions that overlap with those described with reference to FIG. 4 and FIG. 5 will not be provided or simplified.

Referring to FIG. 17, a buffer layer BF, first, second, and third insulating layers IL1, IL2, and IL3, a first pad PD1a′, an insulating layer HVIA, a first touch insulating layer YIL1, an anti-etching layer PL1, and a second touch insulating layer YIL2 may be located in the pad area PA on the substrate SUB. The first pad PD1a′ may include stacked first, second, third, and fourth pad electrodes PE1′, PE2, PE3, and PE4.

The third insulating layer IL3 may be located in the pad area PA on the second insulating layer IL2. The third insulating layer IL3 may cover an edge of the first pad electrode PE1′, and may expose an upper surface of the first pad electrode PE1′.

The first pad electrode PE1′ may be located in the pad area PA on the second insulating layer IL2. In one or more embodiments, the first pad electrode PE1′ may include a same material as the second gate electrode GE2. For example, the first pad electrode PE1′ may be concurrently (e.g., simultaneously) formed through a same process as the second gate electrode GE2.

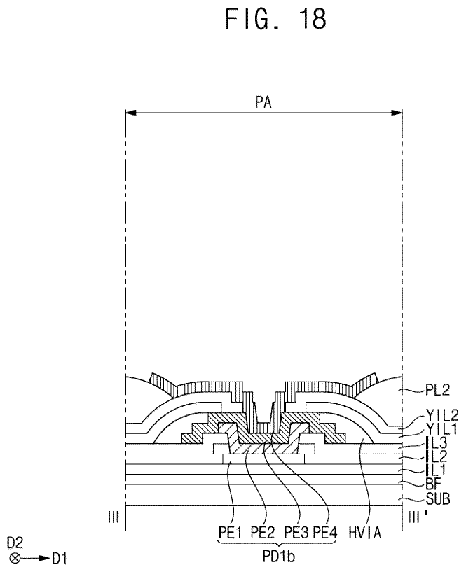

FIG. 18 is a cross-sectional view taken along the line III-III′ of FIG. 3 according to one or more embodiments of the present disclosure. Hereinafter, descriptions that overlap with those described with reference to FIG. 4 and FIG. 5 will not be provided or simplified.

Referring to FIG. 18, a buffer layer BF, first, second, and third insulating layers IL1, IL2, and IL3, a first pad PD1b, an insulating layer HVIA, a first touch insulating layer YIL1, a second touch insulating layer YIL2, and an anti-etching layer PL2 may be located in the pad area PA on the substrate SUB. The first pad PD1b may include stacked first, second, third, and fourth pad electrodes PE1, PE2, PE3, and PE4.

The second touch insulating layer YIL2 may be located in the pad area PA on the first touch insulating layer YIL1. For example, the second touch insulating layer YIL2 may cover the first touch insulating layer YIL1, and may be located along the profile of the first touch insulating layer YIL1 to a portion of an upper surface of the third pad electrode PE3 with a substantially uniform thickness. Accordingly, the second touch insulating layer YIL2 may cover an end of the first touch insulating layer YIL1. A lower surface of the second touch insulating layer YIL2 may contact upper surfaces of the third pad electrode PE3 and the first touch insulating layer YIL1. An upper surface of the second touch insulating layer YIL2 may contact the fourth pad electrode PE4 and the anti-etching layer PL2. Additionally, an opening exposing the third pad electrode PE3 may be defined in the second touch insulating layer YIL2.

The anti-etching layer PL2 may be located in the pad area PA on the second touch insulating layer YIL2. For example, an upper surface of the anti-etching layer PL2 may contact an end of the fourth pad electrode PE4. The anti-etching layer PL2 may be located between the second touch insulating layer YIL2 and the end of the fourth pad electrode PE4. An opening exposing the third pad electrode PE3 may be defined in the anti-etching layer PL2. In one or more embodiments, the anti-etching layer PL2 may include a same material as the third touch insulating layer YIL3. For example, the anti-etching layer PL2 may be formed through the same process as the third touch insulating layer YIL3.

The anti-etching layer PL2 may prevent or reduce the first touch insulating layer YIL1 from being removed when the fourth pad electrode PE4 is etched. For example, during the compression process to attach the driving integrated circuit DIC and the circuit board PCB onto the substrate SUB, cracks may be prevented or reduced from occurring in the first touch insulating layer YIL1 in the pad area PA, and corrosion of the first pad PD1b due to moisture permeation into the insulating layer HVIA through the cracks may be suppressed or reduced. Accordingly, it may prevent or reduce defects in the display device DD due to moisture permeation.

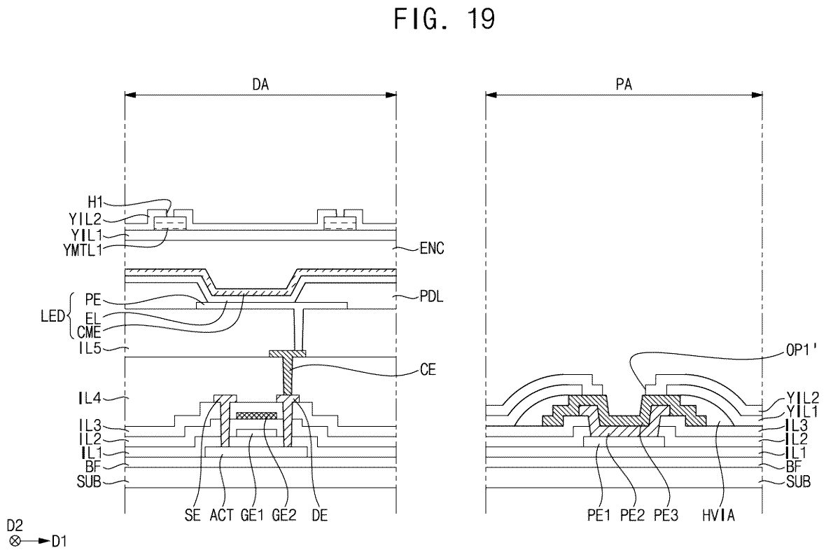

FIGS. 19, 20, 21, 22, and 23 are cross-sectional views illustrating an example of a method of manufacturing the display device of FIGS. 4 and 18 according to one or more embodiments of the present disclosure. Hereinafter, descriptions that overlap with those described with reference to FIGS. 6, 7, 8, 9, 10, 11, 12, 13, 14, 15, and 16 will not be provided or simplified.

Referring to FIG. 19, the second touch insulating layer YIL2 may be entirely formed in the display area DA and the pad area PA. A first contact hole H1 exposing a portion of an upper surface of the first touch electrode YMTL1 may be formed by removing a portion of the second touch insulating layer YIL2 located in the display area DA through an etching process. Additionally, a first opening OP1′ exposing an upper surface of the third pad electrode PE3 may be formed by removing a portion of the second touch insulating layer YIL2 located in the pad area PA through the etching process.

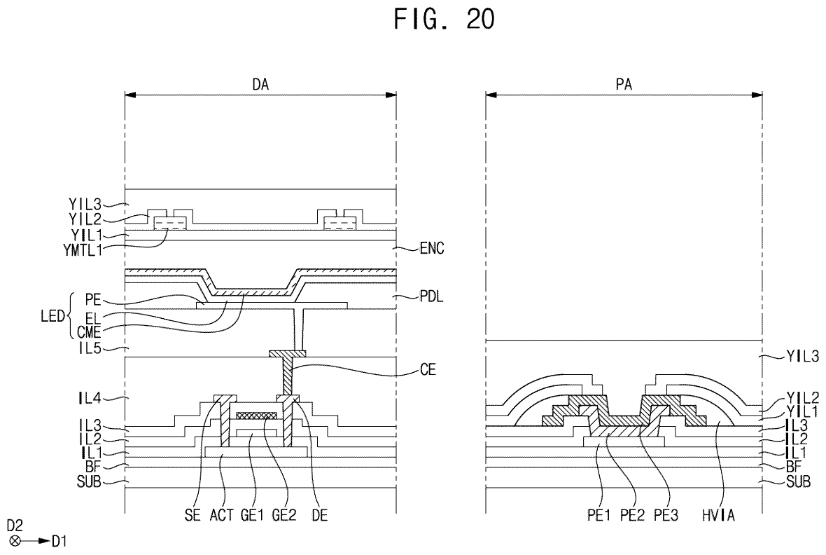

Referring to FIG. 20, the third touch insulating layer YIL3 may be entirely formed in the display area DA and the pad area PA. For example, the third touch insulating layer YIL3 may be formed using an organic insulating material.

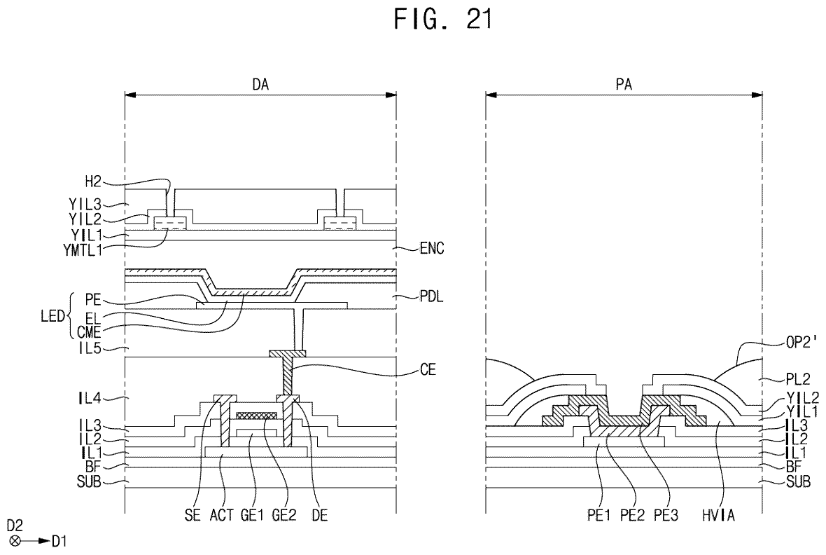

Referring to FIG. 21, the anti-etching layer PL2 may be formed in the pad area PA on the second touch insulating layer YIL2. In one or more embodiments, the anti-etching layer PL2 may be formed using the same material as the third touch insulating layer YIL3. For example, the anti-etching layer PL2 may be concurrently (e.g., simultaneously) formed through the same process as the third touch insulating layer YIL3. For example, the third touch insulating layer YIL3 may be entirely formed in the display area DA and the pad area PA. A second contact hole H2 that overlaps the first contact hole H1 and exposes the first touch electrode YMTL1 may be formed in the display area DA on the third touch insulating layer YIL3 by placing a mask on the third touch insulating layer YIL3 and exposing and developing the third touch insulating layer YIL3 through the mask. At the same time, a second opening OP2′ exposing an upper surface of the anti-etching layer PL2 and the third pad electrode PE3 may be formed by removing a portion of the third touch insulating layer YIL3 in the pad area PA.

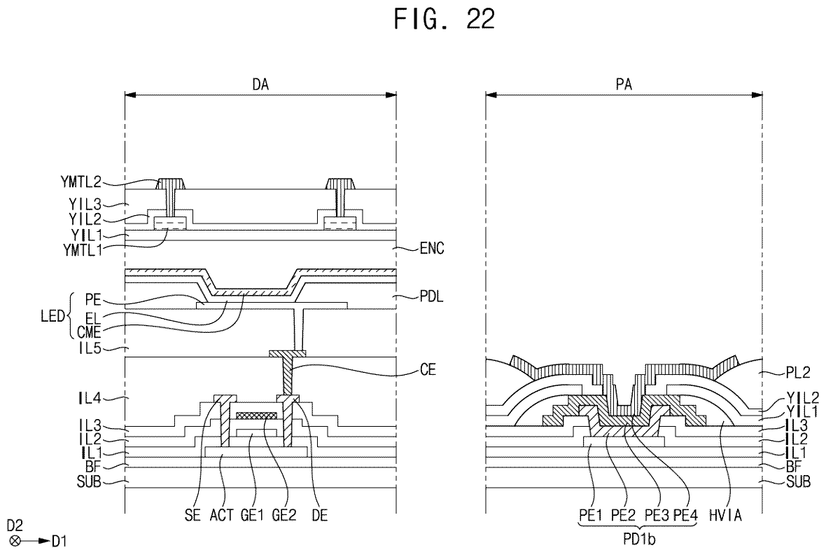

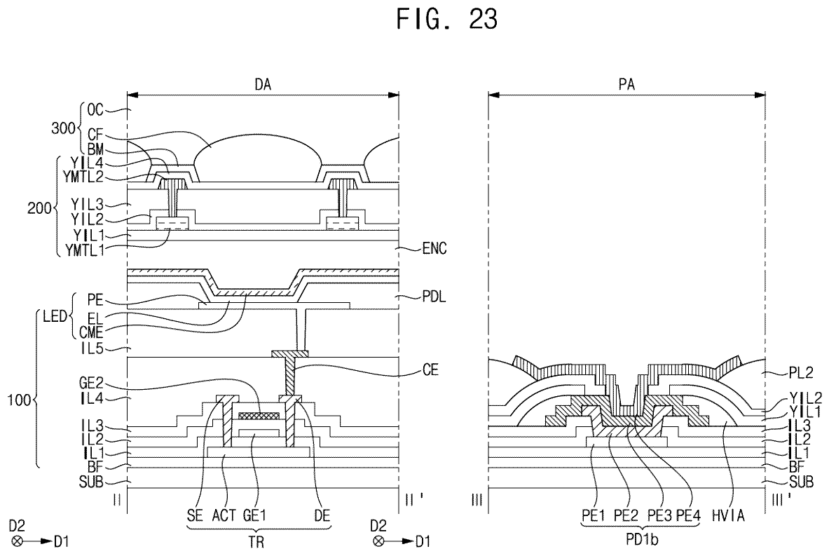

Referring to FIG. 22 and FIG. 23, the fourth pad electrode PE4 may be formed in the pad area PA on the third pad electrode PE3. The fourth pad electrode PE4 may be formed to directly contact the third pad electrode PE3 and the second touch insulating layer YIL2. The fourth pad electrode PE4 may be formed in the second opening OP2′.

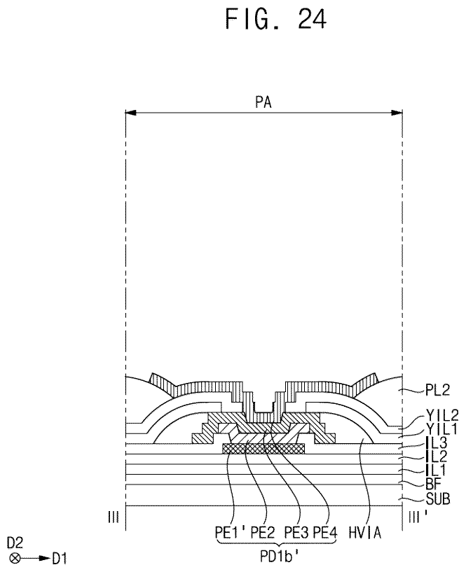

FIG. 24 is a cross-sectional view taken along the line III-III′ of FIG. 3 according to one or more embodiments of the present disclosure. Hereinafter, descriptions that overlap with those described with reference to FIG. 18 will not be provided or simplified.

Referring to FIG. 24, a buffer layer BF, first, second, and third insulating layers IL1, IL2, and IL3, a first pad PD1b′, an insulating layer HVIA, a first touch insulating layer YIL1, a second touch insulating layer YIL2, and an anti-etching layer PL2 may be located in the pad area PA on the substrate SUB. The first pad PD1b′ may include stacked first, second, third, and fourth pad electrodes PE1′, PE2, PE3, and PE4.

The third insulating layer IL3 may be located in the pad area PA on the second insulating layer IL2. The third insulating layer IL3 may cover an edge of the first pad electrode PE1′ and expose an upper surface of the first pad electrode PE1′.

The first pad electrode PE1′ may be formed in the pad area PA on the second insulating layer IL2. The first pad electrode PE1′ may be concurrently (e.g., simultaneously) formed through a same process as the second gate electrode GE2.

In the above, the first pads PD1a, PD1a′, PD1b, and PD1b′ may be substantially the same as the first pads PD1 of FIG. 3. Additionally, the cross-sectional structure of the second pads PD2 may be substantially the same as the cross-sectional structure of the first pads PD1 of FIG. 3.

The display device DD according to one or more embodiments of the present disclosure may be applied to one or more suitable electronic devices. The electronic device according to one or more embodiments may include the display device DD described above, and further include a module of device having other additional functions in addition to the display device DD.

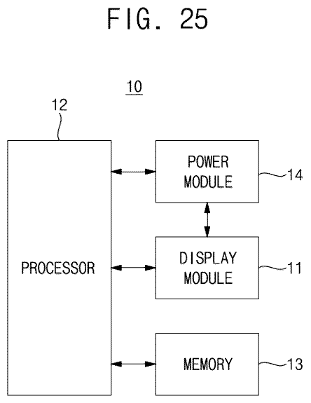

FIG. 25 is a block diagram illustrating an electronic device according to one or more embodiments of the present disclosure.

Referring to FIG. 25, an electronic device 10 according to one or more embodiments may include a display module 11, a processor 12, a memory 13, and a power module 14.

The processor 12 may control the display device DD including the display module 11. The processor 12 may include at least one of a central processing unit (CPU), an application processor (AP), a graphic processing unit (GPU), a communication processor (CP), an image signal processor (ISP), or a controller.

The memory 13 may store date information necessary for operations of the processor 12 and/or the display module 11. When the processor 12 executes an application stored in the memory 13, an image data signal and/or an input control signal may be transmitted to the display module 11, and the display module 11 may processes the received signal and output image information through a display screen.

The power module 14 may include a power supply module, such as a power adapter and/or a battery device, and a power conversion module that converts the power supplied by the power supply module to generate power desired or required for operations of the electronic device 10.

At least one selected from among the components of the electronic device 10 described above may be included in the display device (e.g., the display device DD of FIG. 1) according to the above-described embodiments. Additionally, some of the individual modules functionally included in one module may be included in the display device DD, and other portions may be provided separately from the display device DD. For example, the display device DD may include the display module 11, and the processor 12, the memory 13, and the power module 14 may be provided in the form of other devices within the electronic device 10 other than the display device DD.

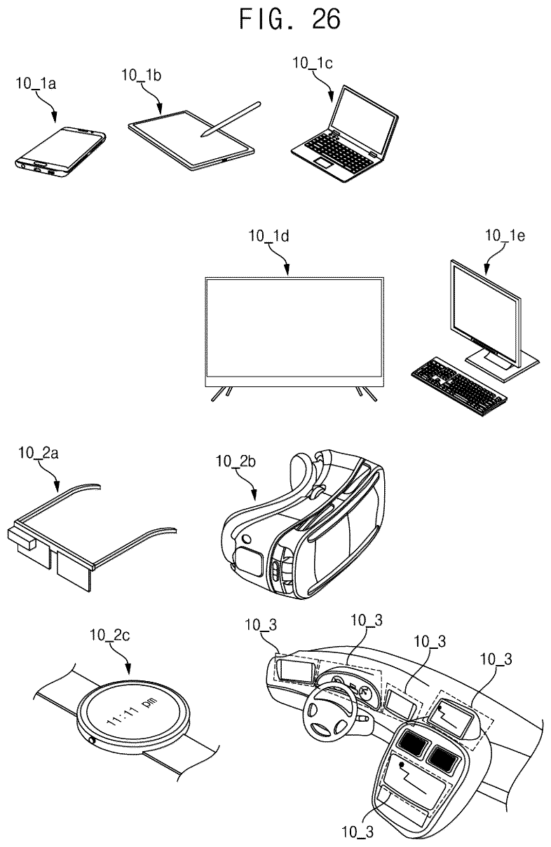

FIG. 26 is a schematic diagram illustrating various suitable electronic devices according to one or more embodiments of the present disclosure.

Referring to FIG. 26, one or more suitable electronic devices 10 to which a display device according to one or more embodiments (e.g., the display device DD of FIG. 1) is applied may include not only image display electronic devices such as a smartphone 10_1a, a tablet PC 10_1b, a laptop 10_1c, a TV 10_1d, and a desktop monitor 10_1e, but also wearable electronic devices including display modules such as smart glasses 10_2a, a head-mounted display 10_2b, and a smart watch 10_2c, and automotive electronic devices 10_3 including display modules such as a dashboard of a car, a center fascia, a center information display (CID) located on a dashboard, and a room mirror display, and/or the like.

Embodiments of the present disclosure may be applied to display devices and electronic devices including the same. For example, embodiments of the present disclosure may be applied to high-resolution smartphones, mobile phones, smart pads, smart watches, tablet PCs, vehicle navigation systems, television, computer monitors, laptops, and/or the like.

In the disclosure, if (e.g., when) it is mentioned that a component (or an area, a layer, a part, and/or the like) is “on”, “located on”, “connected to”, or “coupled to” another component, it refers to that the former component may be directly on, located on, connected to, or coupled to the latter component or a third component may be arranged between the components. In contrast, if (e.g., when) an element is referred to as being “directly on” or “directly located on” another element, there are no intervening element present therebetween.

In the disclosure, in the drawings, thicknesses, ratios, dimensions of the components may be exaggerated for an effective description of the technical contents. The term “and/or” or “or” may include one or more combinations that may be defined by the associated components.

Furthermore, in describing the one or more suitable components, the terms, such as “first” and “second” may be used, but embodiments of the present disclosure are not limited by the terms. The terms are simply for distinguishing the components. For example, a first component may be named a second component, and similarly a second component also may be named a first component while not departing from the scope of the present disclosure. As used herein, a singular expression includes a plural expression unless an exemption is explicitly described in the context. For example, the singular forms “a,” “an,” and “the” are intended to include the plural forms as well, unless the context clearly indicates otherwise. Further, the use of “may” when describing embodiments of the present disclosure refers to “one or more embodiments of the present disclosure.”

Spatially relative terms, such as “beneath,” “below,” “lower,” “above,” “upper,” and/or the like, may be used herein for descriptive purposes, and, thereby, to describe one element or feature's relationship to another element(s) or feature(s) as shown in the drawings. Spatially relative terms are intended to encompass different orientations of a device in use, operation, and/or manufacture in addition to the orientation depicted in the drawings. For example, if (e.g., when) the device in the drawings is turned upside down, elements described as “below” or “beneath” other elements or features would then be oriented “above” the other elements or features. Thus, in one or more embodiments, the example term “below” may encompass both (e.g., simultaneously) an orientation of above and below directions. Furthermore, the device may be otherwise oriented (e.g., rotated 90 degrees or at other orientations), and, as such, the spatially relative descriptors used herein interpreted accordingly.

When the terms, such as “comprise(s)/comprising” and/or “include(s)/including” and/or “has(have)/having, are used in the disclosure, it should be understood that they specify presence of the stated features, numbers, steps, operations, components, parts, and/or one or more (e.g., any suitable) combinations thereof, but do not exclude presence or addition of one or more other features, numbers, steps, operations, components, parts, and/or one or more (e.g., any suitable) combinations thereof. Additionally, the terms “comprise(s)/comprising,” “include(s)/including,” “has(have)/having”, or other similar terms include or support the terms “consisting of” and “consisting essentially of,” indicating the presence of stated features, numbers, steps, operations, parts, and/or components, without or essentially without the presence of other features, numbers, steps, operations, parts, components, and/or groups thereof.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” or “approximately” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display module, the display device, the electronic devices/apparatus, the device-manufacturing apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The foregoing is illustrative of example embodiments and is not to be construed as limiting thereof. Although a few embodiments have been described, those skilled in the art will readily appreciate that many modifications are possible in one or more embodiments without materially departing from the teachings and advantages of the present disclosure. Accordingly, all such modifications are intended to be included within the scope of the present disclosure as defined in the appended claims. Therefore, it is to be understood that the foregoing is illustrative of some example embodiments and is not to be construed as limited to the specific embodiments disclosed, and that modifications to the disclosed embodiments, as well as one or more embodiments, are intended to be included within the scope of the appended claims and equivalents thereof.

What is claimed is:

1. A display device comprising:
a substrate comprising a display area and a pad area located on a side of the display area;
a transistor located in the display area on the substrate;
a plurality of pads located in the pad area, each of the pads comprising first, second, third, and fourth pad electrodes sequentially stacked along a thickness direction;
an insulating layer covering an edge of the third pad electrode;
a touch layer comprising:
a first touch insulating layer located on the transistor, extending from the display area to the pad area, and contacting the third pad electrode and an upper surface of the insulating layer;
a first touch electrode located on the first touch insulating layer;
a second touch insulating layer located on the first touch insulating layer, covering the first touch electrode, extending from the display area to the pad area, and covering an end of the first touch insulating layer in the pad area;
a third touch insulating layer located on the second touch insulating layer and comprising an organic insulating material; and
a second touch electrode located on the third touch insulating layer and connected to the first touch electrode; and
an anti-etching layer located in the pad area on the first touch insulating layer.

2. The display device of claim 1, wherein the anti-etching layer comprises a same material as the first touch electrode.

3. The display device of claim 2, wherein the anti-etching layer is located between the first touch insulating layer and the second touch insulating layer.

4. The display device of claim 2, wherein the anti-etching layer directly contacts an upper surface of the first touch insulating layer and a lower surface of the second touch insulating layer.

5. The display device of claim 2, wherein an edge of the anti-etching layer at least partially overlaps an edge of the fourth pad electrode in a plan view.

6. The display device of claim 2, wherein a lower surface of the second touch insulating layer contacts the third pad electrode, the first touch insulating layer, and the anti-etching layer.

7. The display device of claim 1, wherein the anti-etching layer comprises a same material as the third touch insulating layer.

8. The display device of claim 7, wherein an end of the fourth pad electrode contacts an upper surface of the anti-etching layer.

9. The display device of claim 7, wherein a lower surface of the fourth pad electrode contacts the third pad electrode, the second touch insulating layer, and the anti-etching layer.

10. The display device of claim 7, wherein the anti-etching layer is located between the second touch insulating layer and an end of the fourth pad electrode in the pad area.

11. The display device of claim 7, wherein an opening exposing the third pad electrode is defined in the anti-etching layer, and
wherein the fourth pad electrode is located in the opening.

12. The display device of claim 1, wherein the first touch insulating layer is spaced from the fourth pad electrode in the pad area.

13. The display device of claim 1, wherein the transistor comprises:
an active pattern;
a first gate electrode located on the active pattern; and
a source electrode and a drain electrode each connected to the active pattern,
the display device further comprising:
a second gate electrode located in the display area on the first gate electrode,
wherein the first pad electrode comprises a same material as the first gate electrode or the second gate electrode, and
wherein the second pad electrode comprises a same material as the source electrode and the drain electrode.

14. The display device of claim 13, further comprising:
a connection electrode located in the display area on the source electrode and/or the drain electrode, and connected to the transistor,
wherein the third pad electrode comprises a same material as the connection electrode.

15. The display device of claim 1, wherein the fourth pad electrode comprises a same material as the second touch electrode.

16. The display device of claim 1, further comprising:
an anti-reflection layer comprising:
a black matrix located in the display area on the second touch electrode;
a color filter located on the black matrix; and
an overcoat layer covering the color filter.

17. An electronic device comprising:
a display device comprising:
a substrate comprising a display area and a pad area located on a side of the display area;
a transistor located in the display area on the substrate;
a plurality of pads located in the pad area, each of the pads comprising first, second, third, and fourth pad electrodes sequentially stacked along a thickness direction;
an insulating layer covering an edge of the third pad electrode;
a touch layer comprising:
a first touch insulating layer located on the transistor, extending from the display area to the pad area, and contacting the third pad electrode and an upper surface of the insulating layer;
a first touch electrode located on the first touch insulating layer;
a second touch insulating layer located on the first touch insulating layer, covering the first touch electrode, extending from the display area to the pad area, and covering an end of the first touch insulating layer in the pad area;
a third touch insulating layer located on the second touch insulating layer and comprising an organic insulating material; and
a second touch electrode located on the third touch insulating layer and connected to the first touch electrode; and
an anti-etching layer located in the pad area on the first touch insulating layer; and
a processor configured to control the display device.

18. The electronic device of claim 17, wherein the anti-etching layer comprises a same material as the first touch electrode, and the anti-etching layer is located between the first touch insulating layer and the second touch insulating layer, and
wherein an edge of the anti-etching layer at least partially overlaps an edge of the fourth pad electrode in a plan view.

19. The electronic device of claim 18, wherein the anti-etching layer directly contacts an upper surface of the first touch insulating layer and a lower surface of the second touch insulating layer, and
wherein the lower surface of the second touch insulating layer contacts the third pad electrode, the first touch insulating layer, and the anti-etching layer.

20. The electronic device of claim 17, wherein the anti-etching layer comprises a same material as the third touch insulating layer, and the anti-etching layer is located between the second touch insulating layer and an end of the fourth pad electrode, and
wherein a lower surface of the fourth pad electrode contacts the third pad electrode, the second touch insulating layer, and the anti-etching layer.
